(19) United States
(12) Patent Application Publication
(10) Pub. No.: US 2024/0312960 A1
(43) Pub. Date: Sep. 19, 2024

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Shun TAKEDA, Yokohama Kanagawa (JP); Hiroshi KONO, Himeji Hyogo (JP)

(21) Appl. No.: 18/459,207

(22) Filed: Aug. 31, 2023

(30) Foreign Application Priority Data
Mar. 15, 2023 (JP) P2023-041248

(51) Int. Cl. H01L 25/07; H01L 23/00; H01L 23/498

(52) U.S. Cl. CPC H01L 25/072; H01L 23/49844; H01L 24/32; H01L 24/48; H01L 24/73; H01L 23/367; H01L 2224/32238; H01L 2224/48225; H01L 2224/73265; H01L 2924/1203; H01L 2924/13091

(57) ABSTRACT

According to one embodiment, a semiconductor device includes a plurality of chips, in which the plurality of chips include a first chip, a second chip adjacent to the first chip on the other end side in the first direction, a third chip closer to the other end side in the first direction than the second chip, and a fourth chip adjacent to the third chip on the other end side in the first direction, which are arranged from one end side to the other end side in a first direction, and a first distance between the first chip and the second chip, and a second distance between the third chip and the fourth chip are less than a third distance between, among the plurality of chips, two chips adjacent to each other in a region closer to the other end side in the first direction than the first chip and closer to the one end side in the first direction than the fourth chip.

### CROSS-REFERENCE TO RELATED APPLICATION

This application is based upon and claims the benefit of priority from Japanese Patent Application No. 2023-041248, filed Mar. 15, 2023, the entire contents of which are incorporated herein by reference.

### FIELD

Embodiments described herein relate generally to a semiconductor device.

### BACKGROUND

A power module is known as a semiconductor device that achieves high output. The power module is configured as one package in which a plurality of power semiconductors are mounted.

### DESCRIPTION OF THE DRAWINGS

FIG. 1 is a circuit view showing an example of a circuit configuration of a semiconductor device according to an embodiment.

FIG. 2 is a plan view showing a configuration of the semiconductor device according to the embodiment.

FIG. 3 is a cross-sectional view taken along the line III-III in FIG. 2, showing an example of the cross-sectional structure of the semiconductor device according to the embodiment.

FIG. 4 is a plan view showing the arrangement of a plurality of semiconductor elements in the semiconductor device according to the embodiment.

FIG. 5 is a graph showing the maximum temperature of each semiconductor element in a case where the semiconductor device according to the embodiment and a semiconductor device according to a comparative example are respectively used.

FIG. 6 is a plan view showing a configuration of a semiconductor device according to a first modification example.

FIG. 7 is a view showing the arrangement of a plurality of semiconductor elements in the semiconductor device according to the first modification example.

FIG. 8 is a circuit view showing an example of a circuit configuration of a semiconductor device according to a second modification example.

FIG. 9 is a view showing the arrangement of a plurality of semiconductor elements in the semiconductor device according to the second modification example.

FIG. 10 is a view showing the arrangement of the plurality of semiconductor elements in the semiconductor device according to the second modification example.

FIG. 11 is a plan view showing a portion of a semiconductor device according to another example.

### DETAILED DESCRIPTION

Embodiments provide a semiconductor device improved in the reliability.

In general, according to one embodiment, a semiconductor device includes a plurality of chips, in which the plurality of chips include a first chip, a second chip adjacent to the first chip on the other end side in the first direction, a third chip closer to the other end side in the first direction than the second chip, and a fourth chip adjacent to the third chip on the other end side in the first direction, which are arranged from one end side to the other end side in a first direction, and a first distance between the first chip and the second chip, and a second distance between the third chip and the fourth chip are less than a third distance between, among the plurality of chips, two chips adjacent to each other in a region closer to the other end side in the first direction than the first chip and closer to the one end side in the first direction than the fourth chip.

Hereinafter, embodiments will be described with reference to drawings. The dimensions and ratios of each drawing are not necessarily the same as actual ones.

In the following description, the same reference numerals are added to elements having substantially the same function and configuration. Letters or numerals different from each other may be added to the end of the same reference numerals when specifically distinguishing between elements having similar configurations.

### 1. Embodiment

A semiconductor device according to an embodiment will be described.

A semiconductor device according to the embodiment is a power module. The semiconductor device according to the embodiment is applied to, for example, a power conversion device for a railway vehicle, an industrial device for a renewable energy power generation system, or the like.

### 1.1 Configuration

A configuration of the semiconductor device according to the embodiment will be described.

### 1.1.1 Circuit Configuration

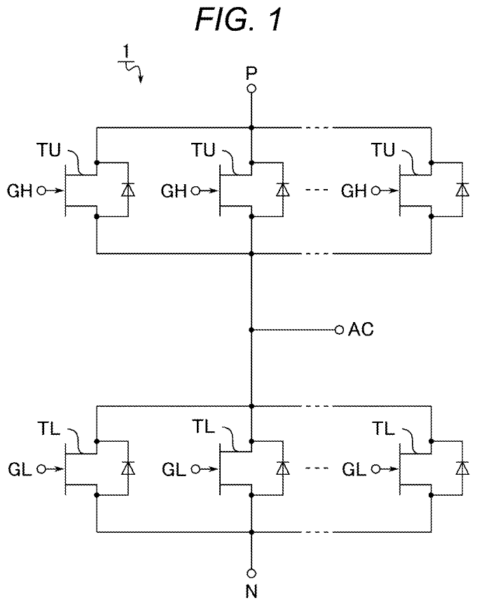

A circuit configuration of the semiconductor device according to the embodiment will be described with reference to FIG. 1. FIG. 1 is a circuit view showing an example of the circuit configuration of the semiconductor device according to the embodiment. In the example of FIG. 1, a semiconductor device 1 includes a plurality of transistors TU and TL as internal semiconductor elements. In the following description, each of the plurality of transistors TU and TL is also simply referred to as a transistor T when the plurality of transistors TU and TL are not distinguished.

A plurality of transistors T are metal-oxide-semiconductor (MOS) transistors. The plurality of transistors T are n-type transistors. In the embodiment, the number of at least either of the plurality of transistors TU and TL is four or more.

The plurality of transistors TU are connected in parallel between a node P and a node alternating current (AC). The node P is an input terminal of the semiconductor device 1. The node P has, for example, a positive polarity in the circuit configuration of the semiconductor device 1. The node AC is an output terminal of the semiconductor device 1. The node AC is connected to a monitor terminal, as will be described later. In the following description, the semiconductor elements provided between the node P and the node AC are also referred to as upper semiconductor elements.

Each transistor TU has a drain end connected to the node P, a source end connected to the node AC, and a gate end connected to a node GH. The node GH is a control terminal.

A plurality of transistors TL are connected in parallel between the node AC and a node N. The node N is an input terminal of the semiconductor device 1. The node N has, for example, a negative polarity in the circuit configuration of the semiconductor device 1. The node N is connected to a monitor terminal different from the monitor terminal connected to the node AC, as will be described later. In the following description, the semiconductor elements provided between the node AC and the node N are also referred to as lower semiconductor elements.

Each transistor TL has a drain end connected to the node AC, a source end connected to the node N, and a gate end connected to a node GL. The node GL is a control terminal.

With the configuration as described above, the semiconductor elements in the semiconductor device 1 can be controlled by the voltage supplied from the outside of the semiconductor device 1.

The circuit configuration of the semiconductor device 1 is not limited to the example in FIG. 1. The semiconductor device 1 may have, for example, a plurality of insulated-gate bipolar transistors (IGBTs) instead of the plurality of transistors T as internal semiconductor elements.

### 1.1.2 Structure of Semiconductor Device

Next, a structure of the semiconductor device 1 according to the embodiment will be described.

### 1.1.2.1 Planar Structure

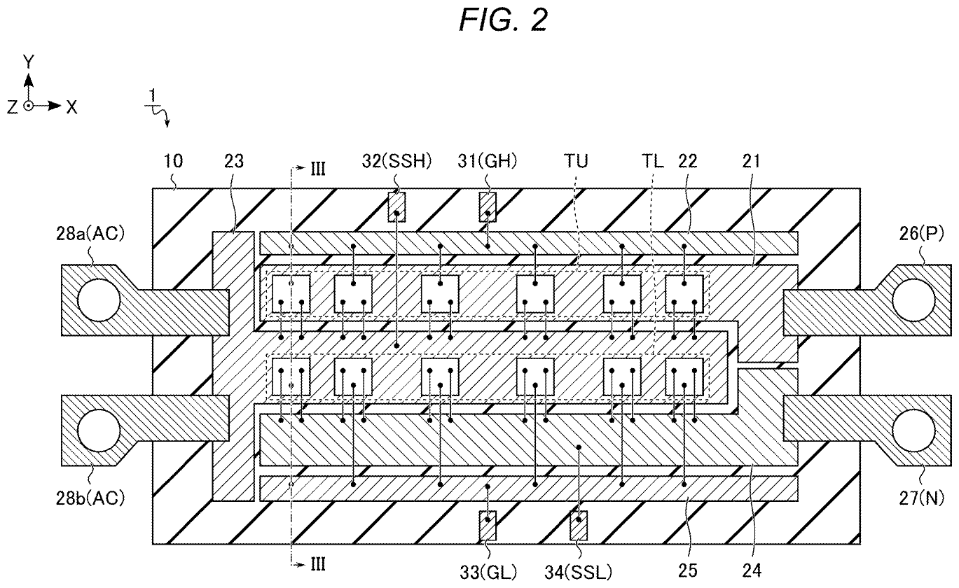

First, a planar structure of the semiconductor device 1 according to the embodiment will be described with reference to FIG. 2. FIG. 2 is a plan view showing the configuration of the semiconductor device according to the embodiment.

The semiconductor device 1 further includes an insulating member 10 and conductors 21, 22, 23, 24, 25, 26, 27, 28a, 28b, 31, 32, 33, and 34. The semiconductor device 1 further includes a base substrate (not shown in FIG. 2).

The insulating member 10 is provided on the base substrate. The base substrate is a support body having a flat portion. The base substrate contains, for example, copper or ceramics. The insulating member 10 contains, for example, resin or ceramics. The resin is, for example, poly-phenylene sulfide (PPS). Hereinafter, the structure of the semiconductor device 1 is described by using the base substrate, an X direction in a plane parallel to the upper surface of the insulating member 10, a Y direction orthogonal to the X direction in the plane, and a Z direction perpendicular to the plane.

The conductors 21, 22, 23, 24, and 25 are provided on the insulating member 10. The conductors 21, 22, 23, 24, and 25 are spaced apart from each other. Each of the conductors 21, 22, 23, 24, and 25 has a portion extending along the X direction. A portion of the conductor 22 extending along the X direction, a portion of the conductor 21 extending along the X direction, a portion of the conductor 23 extending along the X direction, a portion of the conductor 24 extending along the X direction, and a portion of the conductor 25 extending along the X direction are arranged along the Y direction in this order. Each of the conductors 21, 23, and 24 further has a portion extending in the Y direction. The portion of the conductor 23 extending in the Y direction and the portion of each of the conductors 21 and 24 extending in the Y direction are arranged at different ends along the X direction. In the following description, among the portions of the conductors 21, 23, and 24 extending in the Y direction, the side on which the portion of the conductor 23 extending in the Y direction is located is referred to as one end side in the X direction. Among the portions of the conductors 21, 23, and 24 extending in the Y direction, the side on which the portions of the conductors 21 and 24 extending in the Y direction are located is referred to as the other end side in the X direction.

The plurality of transistors TU are arranged in the X direction on the upper surface of the portion of the conductor 21 extending along the X direction. FIG. 2 shows an example in which six transistors TU are arranged. A drain end of each transistor TU is provided on the lower surface of the transistor TU. A source end and a gate end of each transistor TU are provided on the upper surface of the transistor TU. The drain end of each transistor TU is electrically connected to the conductor 21. The source end of each transistor TU is electrically connected to the conductor 23 via a wire. The gate end of each transistor TU is electrically connected to the conductor 22 via a wire.

The plurality of transistors TL are arranged in the X direction on the upper surface of the portion of the conductor 23 extending in the X direction. FIG. 2 shows an example in which six transistors TL are arranged. A drain end of each transistor TL is provided on the lower surface of the transistor TL. A source end and a gate end of each transistor TL are provided on the upper surface of the transistor TL. The drain end of each transistor TL is electrically connected to the conductor 23. The source end of each transistor TL is electrically connected to the conductor 24 via a wire. The gate end of each transistor TL is electrically connected to the conductor 25 via a wire.

The conductor 26 is electrically connected to the portion of the conductor 21 extending in the Y direction at the other end side along the X direction. The conductor 26 functions as the node P. That is, the conductor 26 is an input terminal having a positive polarity.

The conductor 27 is electrically connected to the portion of the conductor 24 extending in the Y direction at the other end side along the X direction. The conductor 27 functions as the node N. That is, the conductor 27 is an input terminal having a negative polarity.

The conductors 28a and 28b are electrically connected to the portion of the conductor 23 extending in the Y direction at one end side along the X direction. The conductors 28a and 28b function as the node AC. That is, the conductors 28a and 28b are output terminals.

The conductors 31, 32, 33, and 34 are provided on the insulating member 10 like the conductors 21, 22, 23, 24, and 25. The conductor 31 is electrically connected to the conductor 22 via a wire. The conductor 31 functions as the node GH. That is, the conductor 31 corresponds to the control terminals of the plurality of transistors TU. The conductor 32 is electrically connected to the conductor 23 via a wire. The conductor 32 functions as a monitor terminal SSH connected to the node AC. The conductor 33 is electrically connected to the conductor 25 via a wire. The conductor 33 functions as the node GL. That is, the conductor 33 corresponds to the control terminals of the plurality of transistors TL. The conductor 34 is electrically connected to the conductor 24 via a wire. The conductor 34 functions as a monitor terminal SSL connected to the node N.

### 1.1.2.2 Cross-Sectional Structure

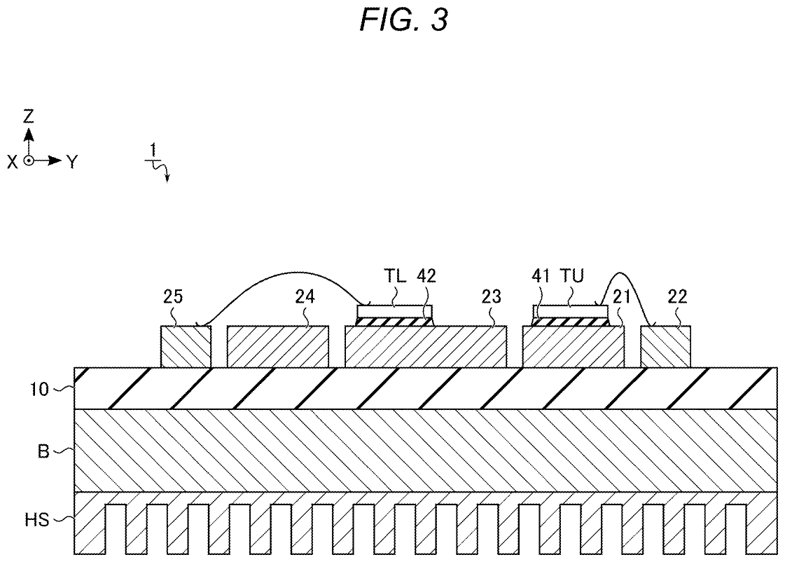

Next, a cross-sectional structure of the semiconductor device 1 according to the embodiment will be described with reference to FIG. 3. FIG. 3 is a cross-sectional view taken along the line III-III in FIG. 2, showing an example of the cross-sectional structure of the semiconductor device according to the embodiment.

The semiconductor device 1 further includes, for example, a heat removing member HS.

The heat removing member HS is a heat sink. The heat removing member HS is provided entirely on the lower surface of a base substrate B used as the above-described support body, for example. The heat removing member HS has a relatively large surface area due to the irregularities on the lower surface. The heat removing member HS contains, for example, copper or ceramics. The heat removing member HS may be formed integrally with the base substrate B.

Each transistor TU is provided on the upper surface of the conductor 21 via an adhesive member 41. The adhesive member 41 physically and electrically connects the drain end of each transistor TU and the conductor 21.

Each transistor TL is provided on the upper surface of the conductor 23 via an adhesive member 42. The adhesive member 42 physically and electrically connects the drain end of each transistor TL and the conductor 23.

### 1.1.2.3 Arrangement of Plurality of Semiconductor Elements

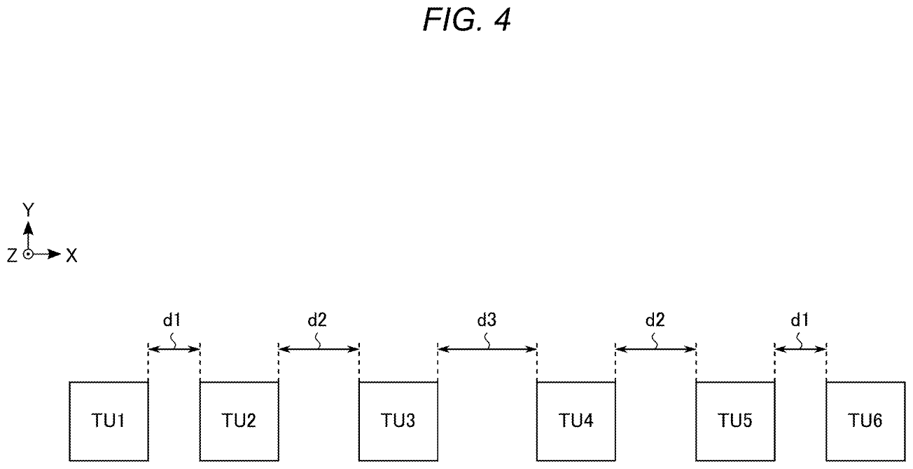

Next, the arrangement of a plurality of semiconductor elements in the semiconductor device 1 according to the embodiment will be described with reference to FIG. 4. FIG. 4 is a plan view showing the arrangement of the plurality of semiconductor elements in the semiconductor device according to the embodiment. The arrangement of the plurality of transistors TL can be the same as the arrangement of the plurality of transistors TU. Therefore, in FIG. 4, only the plurality of transistors TU are illustrated. In FIG. 4, illustration of the conductor 21 is omitted.

The six transistors TU arranged from one end side to the other end side in the X direction are hereinafter referred to as transistors TU1, TU2, TU3, TU4, TU5, and TU6.

The distance between the transistors TU1 and TU2 and the distance between the transistors TU5 and TU6 are distances d1. The distance between the transistors TU2 and TU3 and the distance between the transistors TU4 and TU5 are distances d2. The distance between the transistors TU3 and TU4 are distances d3.

The distance d1 is less than the distance d3. The distance d2 is equal to or greater than the distance d1 and equal to or smaller than the distance d3.

Even when the number of transistors TU arranged in the X direction is 4, 5, or 7 or more, the plurality of transistors TU may be arranged in the same manner as in the case where the number of transistors TU arranged in the X direction is 6.

More specifically, when only four transistors TU are arranged in the X direction, the plurality of transistors TU do not include the transistors TU3 and TU4, but include the transistors TU1, TU2, TU5, and TU6, for example. In this case, the distance between the transistors TU2 and TU5 is the distance d3.

When only five transistors TU are arranged in the X direction, the plurality of transistors TU include, for example, the transistors TU1, TU2, TU5, and TU6, and the transistor TU3 or TU4. In this case, at least one of the distance between the transistors TU2 and TU3 and the distance between the transistors TU3 and TU5 or at least one of the distance between the transistors TU2 and TU4 and the distance between the transistors TU4 and TU5 is the distance d3.

When seven or more transistors TU are arranged in the X direction, the plurality of transistors TU include one or more transistors TU between the transistors TU2 and TU3 and between the transistors TU4 and TU5, for example. In this case, in the X direction, the distance between two transistors TU adjacent to each other, which is provided in a region closer to the other end side than the transistor TU1 and closer to one end side than the transistor TU4, and a region closer to the other end side than the transistor TU3 and closer to one end side than the transistor TU6, is equal to or greater than the distance d1 and equal to or smaller than the distance d3. The distance between two transistors TU adjacent to each other in a region closer to the other end side than the transistor TU1 and closer to one end side than the transistor TU4 is equal to or greater than the distance between two transistors TU adjacent to each other closer to one end side in the X direction than the two transistors TU adjacent to each other. The distance between two transistors TU adjacent to each other in a region closer to the other end side than the transistor TU3 and closer to one end side than the transistor TU6 is equal to or greater than the distance between two transistors TU adjacent to each other closer to the other end side in the X direction than the two transistors TU.

With the configuration as described above, the plurality of transistors T according to the embodiment are arranged such that, for example, the distance between two transistors T adjacent to each other becomes smaller in steps (gradually) from the central region toward one end side and the other end side along the X direction, respectively. The central region along the X direction is, for example, a region interposed between two semiconductor elements where the distance between the two semiconductor elements adjacent to each other in the X direction is maximum. When there are a plurality of sets including the two semiconductor elements, the central region may be a region interposed between two semiconductor elements provided in any of the plurality of sets.

According to the embodiment, the reliability of the semiconductor device 1 can be improved.

The semiconductor device 1 of the embodiment includes the plurality of transistors TU arranged along the X direction. The plurality of transistors TU include the transistors TU1, TU2, TU3, TU4, TU5, and TU6 arranged in this order from one end side to the other end side in the X direction. The distance d1 between transistors TU1 and TU2 and the distance d1 between transistors TU5 and TU6 are less than the distance d3 between transistors TU3 and TU4. With such a configuration, for example, due to thermal interference between the transistors TU, the temperatures of the transistor TU provided in the central region are prevented from rising compared to the transistors TU provided in the regions on one end side and the other end side along the X direction. Thereby, the temperatures of the plurality of transistors TU during operation of the semiconductor device 1 can be made uniform. As described above, the reliability of the semiconductor device 1 can be improved.

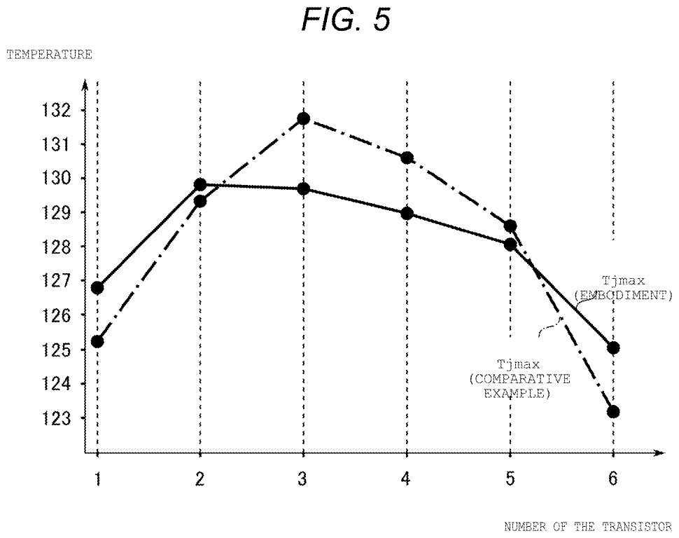

Prevention of the temperature rise of the transistors TU provided in the central region and making the temperatures of the plurality of transistors TU uniform will be described more specifically with reference to FIG. 5. FIG. 5 is a graph showing the maximum temperature of each semiconductor element when the semiconductor device according to the embodiment and a semiconductor device according to a comparative example are respectively used. In FIG. 5, a maximum temperature Tjmax of a plurality of transistors is indicated by a solid line as a result of thermal analysis of operation simulation of the plurality of transistors when the plurality of transistors are arranged in the same manner as in the semiconductor device 1 according to the embodiment. In the comparative example in which six transistors are arranged at equal intervals, the maximum temperature Tjmax of a plurality of transistors is indicated by a dashed line as a result of thermal analysis of operation simulation of the plurality of transistors. The vertical and horizontal axes in FIG. 5 are the temperature and the number of transistors counted from one end side along the X direction, respectively. In the operation simulations of the embodiment and the comparative example, the amount of heat generated per volume of each transistor is the same. As each transistor, for example, an element to which a current of about 600 A is supplied and having a rated maximum temperature of about 150° C. is assumed.

In the above operation simulation, each transistor has a vertical length and a horizontal length of 7.5 mm. In the operation simulation according to the embodiment, the distances d1, d2, and d3 are 2 mm, 5.75 mm, and 7 mm, respectively. In the operation simulation according to the comparative example, each distance between two transistors adjacent to each other is 4.5 mm. In the layout as described above, the distance between the transistor closest to one end side and the transistor closest to the other end side in the embodiment is the same as the distance between the transistor closest to one end side and the transistor closest to the other end side in the comparative example. That is, in the embodiment and the comparative example, a plurality of transistors are provided in regions having the same area.

As shown in FIG. 5, in the comparative example, each of the third and fourth transistors becomes hotter than the other transistors due to the heat generated by the transistors around the third and fourth transistors. For example, the maximum temperature Tjmax of the third transistor in the comparative example rises to around 132° C.

On the other hand, in the embodiment, the temperature rise of each of the third and fourth transistors TU is prevented by reducing the heat generated by the transistors TU around the third and fourth transistors TU with the arrangement of the plurality of transistor TUs as described above. Thereby, the maximum temperature Tjmax of all transistors TU in the embodiment is less than 130° C.

As described above, when the same number of transistors are provided in the same area in the embodiment and the comparative example, the maximum value of the maximum temperature Tjmax of the transistors in the embodiment can be made lower than the maximum value of the maximum temperature Tjmax of the transistors in the comparative example. According to the embodiment, the maximum temperature Tjmax of the plurality of transistors can be made uniform compared to the maximum temperature Tjmax of the plurality of transistors in the comparative example.

The plurality of transistors TU according to the embodiment are arranged such that, for example, the distance between two transistors TU adjacent to each other becomes smaller in steps from the central region toward one end side and the other end side along the X direction, respectively. With such an arrangement, when arranging a plurality of transistors TU in a limited area, it is possible to effectively prevent the temperature rise of the transistors TU due to the heat generated by the transistors TU around each transistor TU.

Next, the improvement of the reliability of the semiconductor device 1 by preventing the temperature rise of the plurality of transistors TU and making the temperature of the plurality of transistors TU uniform will be supplemented. A lifetime Nf of a semiconductor element is predicted, for example, based on the following Equation (1) using the maximum temperature Tjmax. The following Equation (1) is known as a modified Coffin-Manson equation.

$$Equation 1$$

$$N f = A \times Δ T {1}^{- α} \times exp ( \frac{E a}{{k}_{B} \times T 1 max} ) \qquad ( 1 )$$

Values A and a in Equation (1) are constants. A value ΔTj is the temperature difference between the temperature when a semiconductor element stops operating and the maximum temperature Tjmax when the semiconductor element operates. A value Ea is a predetermined activation energy. A value kB is the Boltzmann constant.

Based on the above Equation (1), it is predicted that the lifetime Nf will become shorter as the maximum temperature Tjmax increases. Therefore, according to the embodiment, by preventing the temperature rise of the semiconductor elements provided in the central region and making the temperatures of the plurality of semiconductor elements uniform, it is possible to prevent the decrease in the average value of the lifetimes of the plurality of semiconductor elements.

In the semiconductor device 1 according to the embodiment, the heat removing member HS is provided over the entire lower surface of the base substrate B. Thereby, in addition to natural cooling, the semiconductor device 1 can be cooled via the heat removing member HS. Therefore, the heat dissipation of the semiconductor device 1 can be improved. Therefore, it is possible to prevent the temperature rise of the semiconductor elements. Such a configuration can also improve the reliability of the semiconductor device 1.

### 2. Modification Examples

Next, a semiconductor device according to modification examples will be described. In the following, descriptions of configurations equivalent to those of the embodiment are omitted, and configurations different from the embodiment are mainly described.

### 2.1 First Modification Example

The semiconductor device according to a first modification example differs from the semiconductor device according to the embodiment in that a plurality of upper transistors and a plurality of lower transistors are arranged in a matrix on a conductor. Configurations different from the embodiment will be mainly described below.

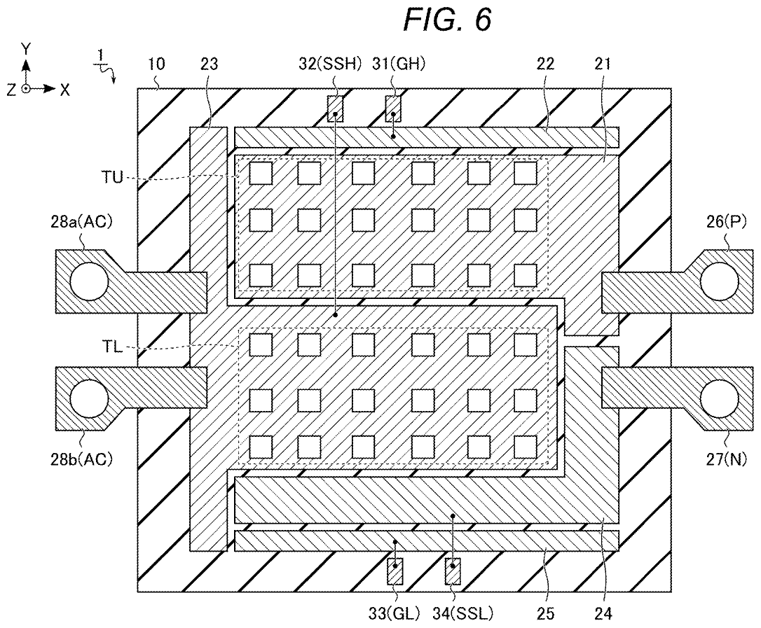

A configuration of the semiconductor device 1 according to the first modification example will be described with reference to FIG. 6. FIG. 6 is a plan view showing the configuration of a semiconductor device according to the first modification example.

In the first modification example, the semiconductor device 1 includes 18 transistors TU and 18 transistors TL. In addition, in FIG. 6, in order to make the arrangement of a plurality of transistors T easier to understand, the illustration of wires connected to the source end and the gate end of each transistor T is omitted.

A plurality of transistors TU are arranged in a matrix on the upper surface of the portion of the conductor 21 extending along the X direction. Since the electrical connection between the drain end, the source end, and the gate end of each transistor TU is the same as the electrical connection between the drain end, the source end, and the gate end of each transistor TU according to the embodiment, the description thereof is omitted.

A plurality of transistors TL are arranged in a matrix on the upper surface of the portion of the conductor 23 extending along the X direction. Since the electrical connection between the drain end, the source end, and the gate end of each transistor TL is the same as the electrical connection between the drain end, the source end, and the gate end of each transistor TL according to the embodiment, the description thereof is omitted.

With the plurality of transistors T arranged in a matrix as described above, the plurality of transistors T are also arranged in a matrix such that six transistors T are arranged in the X direction and the Y direction. The number of transistors T arranged in the Y direction is, for example, four or more.

Since the cross-sectional structure of the semiconductor device 1 in a YZ cross-section is the same as the cross-sectional structure of the semiconductor device in the embodiment except that the number of transistors T is different, the description and illustration thereof is omitted.

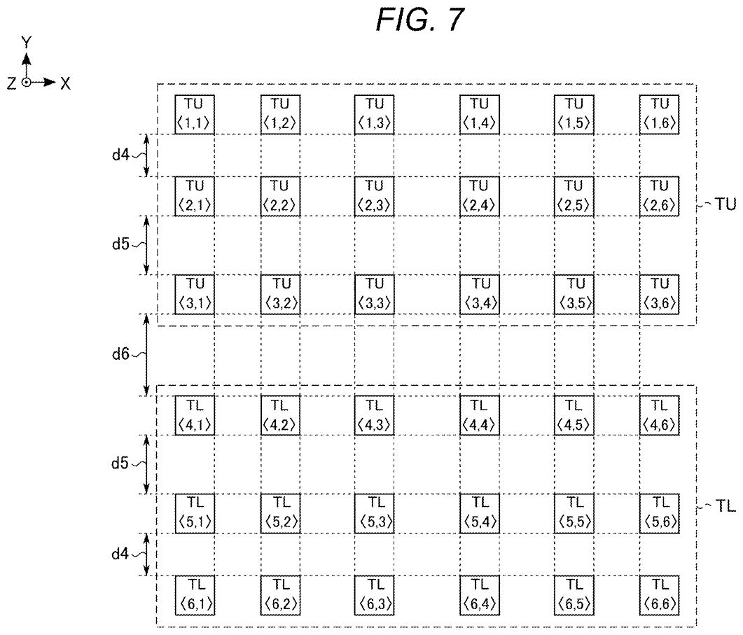

Next, the arrangement of semiconductor elements according to the first modification example will be described with reference to FIG. 7. FIG. 7 is a view showing the arrangement of a plurality of semiconductor elements in the semiconductor device according to the first modification example. In FIG. 7, the arrangement of a plurality of transistors T is illustrated. In FIG. 7, illustration of the conductors 21 and 23 is omitted. In the following description, the side on which, among the transistors TU and TL, the transistors TU are provided is referred to as one end side in the Y direction. The side on which, among the transistors TU and TL, the transistors TL are provided is referred to as the other end side in the Y direction.

The plurality of transistors T are associated with a set including rows and columns. A transistor T associated with a row i₁ and a column j₁ is denoted by a transistor T<i₁, j₁>. In the example shown in FIG. 7, 11 and j₁ are each an integer of 1 or more and 6 or less.

Since the arrangement of six transistors T<i₂, 1> to T<i₂, 6> provided in each row can be the same as the arrangement of the plurality of transistors T in the embodiment, the description thereof is omitted. Here, i₂ is any integer of 1 or more and 6 or less.

In the following, the arrangement of the plurality of transistors T provided in each column is described by using six transistors TU<1, j₂>, TU<2, j₂>, TU<3, j₂>, TL<4, j₂>, TL<5, j₂>, and TL<6, j₂> as an example. Here, j₂ is any integer of 1 or more and 6 or less.

The distance between the transistors TU<1, j₂> and TU<2, j₂> and the distance between the transistors TL<5, j₂> and TL<6, j₂> is a distance d4. The distance between the transistors TU<2, j₂> and TU<3, j₂> and the distance between the transistors TL<4, j₂> and TL<5, j₂> is a distance d5. The distance between the transistors TU<3, j₂> and TL<4, j₂> is a distance d6.

The distance d4 is less than the distance d6. The distance d5 is equal to or greater than the distance d4 and equal to or smaller than the distance d6.

Even when the number of transistors T arranged in the Y direction is 4, 5, or 7 or more, the plurality of transistors T can be arranged in the same manner as the arrangement of the plurality of transistors T according to the embodiment except that the directions are different in each column.

In the first modification example described above, the semiconductor device 1 includes, for example, the same number of transistors TU and TL in each column. Meanwhile, the first modification example is not limited thereto. In each column, the number of transistors TU and the number of transistors TL may differ from each other.

With the configuration as described above, the plurality of transistors T according to the first modification example are arranged such that, for example, the distance between two transistors T adjacent to each other becomes smaller in steps (gradually) from the central region toward one end side and the other end side in the Y direction, respectively. The central region along the Y direction is, for example, a region interposed between two semiconductor elements in which the distance between two semiconductor elements adjacent to each other in the Y direction is the maximum in each column. When there are a plurality of sets including the two semiconductor elements, the central region may be a region interposed between two semiconductor elements provided in any of the plurality of sets.

According to the first modification example, even when a plurality of semiconductor elements are arranged in a matrix in the semiconductor device 1, the same effects as those of the embodiment can be obtained.

### 2.2 Second Modification Example

A semiconductor device according to a second modification example differs from the semiconductor device according to the first modification example in that two different types of semiconductor elements are provided. In the following, configurations different from the embodiment and the first modification example will be mainly described.

### 2.2.1 Circuit Configuration

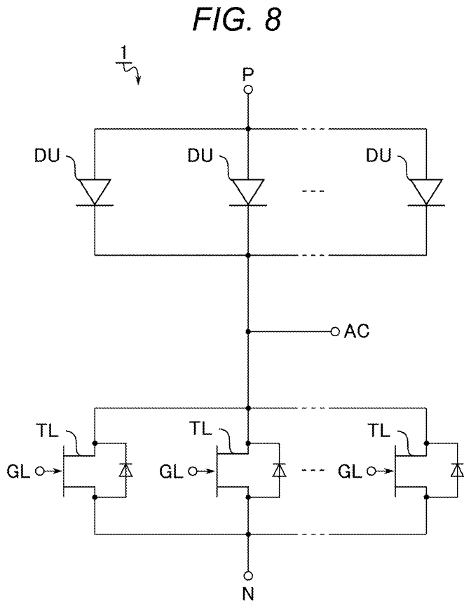

A circuit configuration of a semiconductor device according to the second modification example will be described with reference to FIG. 8. FIG. 8 is a circuit view showing an example of the circuit configuration of the semiconductor device according to the second modification example. In the example of FIG. 8, the semiconductor device 1 includes a plurality of diodes DU and a plurality of transistors TL as internal semiconductor elements. In the following description, each of the plurality of diodes DU and the plurality of transistors TL is simply referred to as a semiconductor element E when the plurality of diodes DU and the plurality of transistors TL are not distinguished.

The plurality of diodes DU are connected in parallel between a node P and a node AC. Each diode DU has an anode connected to the node P and a cathode connected to the node AC.

Other configurations are substantially the same as the circuit configuration of the semiconductor device according to the embodiment.

### 2.2.2 Planar Structure

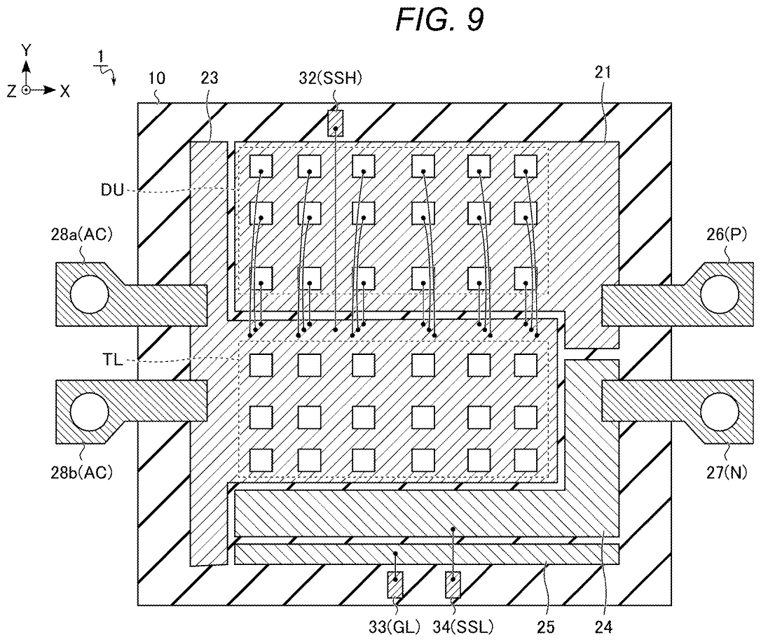

A configuration of the semiconductor device 1 according to the second modification example will be described with reference to FIG. 9. FIG. 9 is a plan view showing the configuration of the semiconductor device according to the second modification example. For the same reason as in the first modification example, the illustration of wires connected to the source end and gate end of each transistor TL is omitted.

In the second modification example, the semiconductor device 1 includes 18 diodes DU and 18 transistors TL.

The plurality of diodes DU are arranged in a matrix on the upper surface of the portion of the conductor 21 extending along the X direction. The anode of each diode DU is provided on the lower surface of the diode. The cathode of each diode DU is provided on the upper surface of the diode DU. The anode of each diode DU is connected on the upper surface of the conductor 21. The cathode of each diode DU is electrically connected to the conductor 23 via a wire. The anode of each diode DU is physically and electrically connected to the conductor 21 by an adhesive member (not shown), like each transistor TU according to the embodiment.

As described above, with the plurality of diodes DU arranged in a matrix similar to the plurality of transistors TL, a plurality of semiconductor elements E are arranged in a matrix such that six semiconductor elements E are arranged in the X direction and Y direction as well. In the example shown in FIG. 9, the semiconductor elements E arranged in the Y direction include three diodes DU and three transistors TL. Meanwhile, not limited thereto, the plurality of semiconductor elements E may include, for example, at least two diodes DU and two transistors TL along the Y direction. FIG. 9 shows a case where the semiconductor device 1 includes the same number of diodes DU and transistors TL. Meanwhile, the second modification example is not limited thereto. In each column, the number of diodes DU and the number of transistors TL may differ from each other.

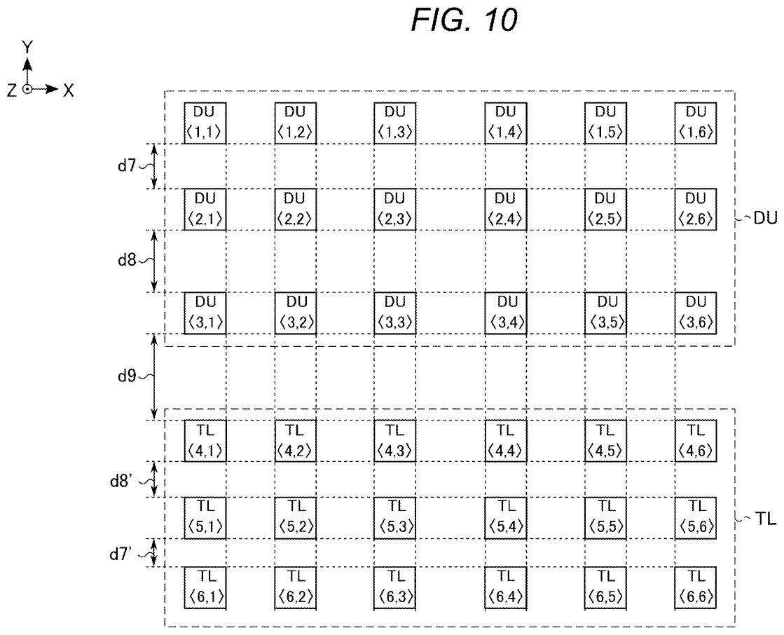

Next, the arrangement of semiconductor elements according to the second modification example will be described with reference to FIG. 10. FIG. 10 is a view showing the arrangement of a plurality of semiconductor elements in the semiconductor device according to the second modification example. FIG. 10 illustrates the arrangement of the plurality of diodes DU and the plurality of transistors TL. In FIG. 10, illustration of the conductors 21 and 23 is omitted. In the following description, the side on which, among the diodes DU and the transistors TL, the diodes DU are provided is referred to as one end side in the Y direction. The side on which, among the diodes DU and the transistors TL, the transistors TL are provided is referred to as the other end side in the Y direction.

The plurality of semiconductor elements E are associated with sets including rows and columns, like the transistors T according to the first modification example. In FIG. 10, the semiconductor element E associated with i₃ row and j₃ column is denoted by a semiconductor element E<i₃, j₃>. i₃ and j₃ are each an integer of 1 or more and 6 or less.

Since the arrangement of six semiconductor elements E<i₄, 1> to E<i₄, 6> provided in each row can be the same as the arrangement of the transistors TU and TL in the embodiment, the description thereof is omitted. Here, i₄ is any integer of 1 or more and 6 or less.

In the following, the arrangement of the plurality of semiconductor elements E provided in each column is described by using three diodes DU<1, j₄>, DU<2, j₄>, and DU<3, j₄>, and three transistors TL<4, j₄>, TL<5, j₄>, and TL<6, j₄> as an example. Here, j₄ is any integer of 1 or more and 6 or less.

The distance between the diodes DU<1, j₄> and DU<2, j₄> is a distance d7. The distance between the diodes DU<2, j₄> and DU<3, j₄> is a distance d8. The distance between the diode DU<3, j₄> and the transistor TL<4, j₄> is a distance d9. The distance between the transistors TL<4, j₄> and TL<5, j₄> is a distance d8′. The distance between the transistors TL<5, j₄> and TL<6, j₄> is a distance d7′.

The distances d7 and d7′ are less than the distance d9. The distance d8 is equal to or greater than the distance d7 and equal to or smaller than the distance d9. The distance d8′ is equal to or greater than the distance d7′ and equal to or smaller than the distance d9.

The distances d7 and d8 between the two diodes DU on the conductor 21 are different from the distances d7′ and d8′ between the two transistors TL on the conductor 23, respectively. More specifically, the distance d7 is wider than the distance d7′. The distance d8 is wider than the distance d8′. The distance d7 may be wider than the distance d8′, for example. With these configurations, the distance between the diodes DU<1, j₄> and DU<3, j₄> provided in succession in the Y direction is wider than the distance between the transistors TL<4, j₄> and TL<6, j₄>. That is, in the Y direction, the diodes DU<1, j₄> to DU<3, j₄> are provided over a wider range than the transistors TL<4, j₄> to TL<6, j_{4>.}

Even when the number of semiconductor elements E arranged in the Y direction is 4, 5, or 7 or more, the plurality of semiconductor elements E may be arranged in the same manner as when six semiconductor elements E arranged in the Y direction are arranged.

More specifically, when only four semiconductor elements E are arranged in the Y direction, the plurality of semiconductor elements E does not include, for example, the diode DU<3, j₄> and the transistor TL<4, j₄>, but include the diode DU<1, j₄> and DU<2, j₄>, and the transistors TL<5, j₄> and TL<6, j₄>. In this case, the distance between the diode DU<2, j₄> and the transistor TL<5, j₄> is the distance d9.

When only five semiconductor elements E are arranged in the Y direction, the plurality of semiconductor elements E include, for example, the diodes DU<1, j₄> and DU<2, j₄>, the transistors TL<5, j₄> and TL<6, j₄>, and the diode DU<3, j₄> or the transistor TL<4, j₄>. In this case, at least one of the distance between the diode DU<2, j₄> and the transistor TL<4, j₄> and the distance between the transistors TL<4, j₄> and TL<5, j₄>, or at least one of the distance between the diodes DU<2, j₄> and DU<3, j₄> and the distance between the diode DU<3, j₄> and the transistor TL<5, j₄> is the distance d9.

When seven or more semiconductor elements E are arranged in the Y direction, the plurality of semiconductor elements E include, for example, one or more semiconductor elements E between the diodes DU<2, j₄> and DU<3, j₄> and between the transistors TL<4, j₄> and TL<5, j₄>. A semiconductor element E that may be provided between the diodes DU<2, j₄> and DU<3, j₄> is the diode DU. In the Y direction, the distance between two diodes DU adjacent to each other provided in a region closer to the other end side than the diode DU<1, j₄> and closer to one end side than the transistor TL<4, j₄> is equal to or greater than the distance d7 and equal to or smaller than the distance d9. The distance between the two diodes DU adjacent to each other in the region is equal to or greater than the distance between two diodes DU adjacent to each other closer to the one end side in the Y direction than the two diodes DU. A semiconductor element E that may be provided between the transistors TL<4, j₄> and TL<5, j₄> is the transistor TL. In the Y direction, the distance between two transistors TL adjacent to each other provided in a region closer to the other end side than the diode DU<3, j₄> and closer to one end side than the transistor TL<6, j₄> is equal to or greater than the distance d7′ and equal to or smaller than the distance d9. The distance between the two transistors TL adjacent to each other in the region is equal to or greater than the distance between two transistors TL adjacent to each other closer to the other end side in the Y direction than the two transistors TL.

When the number of semiconductor elements E arranged in the Y direction is six or more, the plurality of semiconductor elements E may not include the diode DU<3, j₄>, but include the two diodes DU<1, j₄> and DU<2, j₄>, and four or more transistors TL having transistors TL<4, j₄>, TL<5, j₄>, and TL<6, j₄>. In this case, for example, one or more transistors TL are provided between the transistors TL<4, j₄> and TL<5, j₄>. For example, the distance between the diode DU<2, j₄> and the transistor TL<4, j₄> is the distance d9. In the Y direction, the distance between two transistors TL adjacent to each other provided in a region closer to the other end side than the diode DU<2, j₄> and closer to one end side than the transistor TL<6, j₄> is equal to or greater than the distance d7′ and equal to or smaller than the distance d9. The distance between the two transistors TL adjacent to each other provided in the region is equal to or greater than the distance between two transistors TL adjacent to each other closer to the other end side in the Y direction than the two transistors TL.

With the configuration as described above, the plurality of semiconductor elements E according to the second modification example are arranged such that, for example, the distance between two semiconductor elements E adjacent to each other becomes smaller in steps (gradually) from the central region to one end side and the other end side in the Y direction, respectively. The plurality of upper semiconductor elements E and the plurality of lower semiconductor elements E may be arranged asymmetrically with respect to the XZ plane.

According to the second modification example, in the circuit of the semiconductor device 1, even if the load of each semiconductor element E on the upper side is different from the load of each semiconductor element E on the lower side, the same effects as those of the embodiment and the first modification example can be achieved.

To supplement, in the semiconductor device 1, the semiconductor element E having a larger load generates a larger amount of heat than the semiconductor element E having a smaller load. In such a case, in each column, the arrangement of the plurality of semiconductor elements E is set according to the load of the upper semiconductor elements E and the load of the lower semiconductor elements E. For example, the distance between two semiconductor elements E having a larger load may be wider than the distance between two semiconductor elements E having a smaller load. With such a configuration, even if the load on each semiconductor element E on the upper side is different from the load on each semiconductor element E on the lower side, it is possible to effectively prevent the temperature rise of the plurality of semiconductor elements E. Therefore, the reliability of the semiconductor device 1 can be improved.

### 3. Others

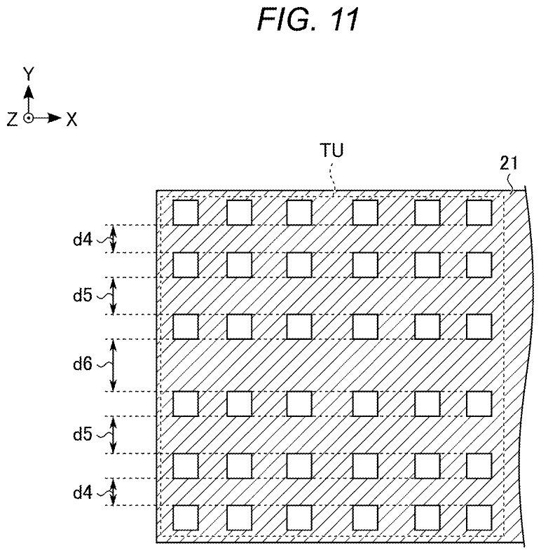

In the above-described first modification example, an example is shown in which, on the upper surfaces of the different conductors 21 and 23, the plurality of semiconductor elements E are arranged such that the distance between two semiconductor elements E adjacent to each other becomes smaller in steps from the central region toward one end side and the other end side in the Y direction, respectively. Meanwhile, the first modification example is not limited thereto. As shown in FIG. 11, the plurality of semiconductor elements E may be arranged on the same conductor such that the distance between two semiconductor elements E adjacent to each other becomes smaller in steps (gradually) from the central region toward one end side and the other end side along the Y direction, respectively. FIG. 11 is a plan view showing a portion of a semiconductor device according to another example. In FIG. 11, 36 upper transistors TU and a portion of the conductor 21 are illustrated. In other examples, the plurality of transistors TL may be arranged on the conductor 23 in the same manner as the plurality of transistors TU. The configuration except for the arrangement of the plurality of transistors T is the same as that of the embodiment and the first modification example. For these reasons, the illustration of the configuration other than the plurality of upper transistors TU and the conductor 21 is omitted.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a plurality of chips,
wherein the plurality of chips comprises a first chip, a second chip adjacent to the first chip on a first end side in a first direction, a third chip provided closer to the first end side in the first direction than the second chip, and a fourth chip adjacent to the third chip on the first end side in the first direction, which are arranged from a second end side to the first end side in the first direction, and
wherein a first distance between the first chip and the second chip, and a second distance between the third chip and the fourth chip are less than a third distance between two chips of the plurality of chips that are adjacent to each other in a region closer to the first end side in the first direction than the first chip, and closer to the second end side in the first direction than the fourth chip.

2. The semiconductor device according to claim 1,
wherein the plurality of chips further comprises a fifth chip adjacent to the second chip in the first direction between the second chip and the third chip, and
wherein a fourth distance between the second chip and the fifth chip, wherein the fourth distance is equal to or greater than the first distance and equal to or less than the third distance.

3. The semiconductor device according to claim 1,
wherein the plurality of chips are arranged on a same conductor.

4. The semiconductor device according to claim 1,
wherein the plurality of chips are arranged in a matrix in the first direction and a second direction orthogonal to the first direction in a plane comprising the first direction,
wherein the plurality of chips further comprises a fifth chip adjacent to the first chip on the first end side in the second direction, a sixth chip arranged closer to the first end side in the second direction than the fifth chip, and a seventh chip adjacent to the sixth chip on the first end side in the second direction, which are arranged from the second end side to the first end side in the second direction together with the first chip,
wherein a fourth distance between the first chip and the fifth chip and a fifth distance between the sixth chip and the seventh chip are less than a sixth distance between, and
wherein the plurality of chips further comprises, at least two chips adjacent to each other in a region closer to the first end side in the second direction than the first chip and closer to the second end side in the second direction than the seventh chip.

5. The semiconductor device according to claim 4,
wherein the plurality of chips are arranged on a first conductor and a second conductor,
wherein the plurality of chips further comprises, a chip arranged on the first conductor connected between a first node and a second node, and
wherein the plurality of chips further comprises, a chip arranged on the second conductor connected between the second node and a third node which are different from the first node.

6. The semiconductor device according to claim 5,
wherein the first chip and the fifth chip are arranged on the first conductor,
wherein the sixth chip and the seventh chip are arranged on the second conductor,
wherein a load on each of the first chip and the fifth chip is larger than the load on each of the sixth chip and the seventh chip; and
wherein the fourth distance is wider than the fifth distance.

7. The semiconductor device according to claim 6,
wherein the first chip and the fifth chip are diodes, and
wherein the sixth chip and the seventh chip are transistors.

8. The semiconductor device according to claim 1,
wherein the plurality of chips are arranged above a same base substrate.

9. The semiconductor device according to claim 8, further comprising:
a heat removing member arranged on a lower surface of the base substrate.
